(19) United States
(12) Patent Application Publication
(10) Pub. No.: US 2023/0395731 A1
(43) Pub. Date: Dec. 7, 2023

(54) SCHOTTKY BARRIER DIODE

(71) Applicants: TAMURA CORPORATION, Tokyo (JP); Novel Crystal Technology, Inc., Saitama (JP)

(72) Inventors: Shinya YAMAGUCHI, Saitama (JP); Yuki UCHIDA, Saitama (JP); Daiki WAKIMOTO, Saitama (JP); Akio TAKATSUKA, Saitama (JP)

(73) Assignees: TAMURA CORPORATION, Tokyo (JP); Novel Crystal Technology, Inc., Saitama (JP)

(21) Appl. No.: 18/327,521

(22) Filed: Jun. 1, 2023

(30) Foreign Application Priority Data
Jun. 1, 2022 (JP) 2022-089752

(51) Int. Cl. H01L 29/872; H01L 29/06; H01L 29/24; H01L 29/40

(52) U.S. Cl. CPC H01L 29/872; H01L 29/0623; H01L 29/24; H01L 29/402

(57) ABSTRACT

A Schottky barrier diode includes an n-type semiconductor layer including a gallium oxide-based semiconductor, an insulating film including SiO₂ and covering a portion of an upper surface of the n-type semiconductor layer, and an anode electrode which is connected to the upper surface of the n-type semiconductor layer to form a Schottky junction with the n-type semiconductor layer and at least a portion of an edge of which is located on the insulating film. The insulating film further includes a first layer in contact with the n-type semiconductor layer and a second layer on the first layer. A refractive index of the first layer is lower than a refractive index of the second layer. The n-type semiconductor layer further includes a guard ring surrounding a junction with the anode electrode.

### CROSS-REFERENCE TO RELATED APPLICATIONS

The present patent application claims the priority of Japanese patent application No. 2022/089752 filed on Jun. 1, 2022, and the entire contents of Japanese patent application No. 2022/089752 are hereby incorporated by reference.

### TECHNICAL FIELD

The present invention relates to a Schottky barrier diode.

### BACKGROUND ART

A Schottky barrier diode is known which has a semiconductor layer formed of a Ga₂O₃-based single crystal and has a field-plate structure to relax electric field concentration at an end portion of an anode electrode (see Patent Literature 1).

The Schottky barrier diode described in Patent Literature 1 is provided with an insulation layer which is formed of an insulating material such as SiO₂ and is provided on a semiconductor layer, and an anode electrode which is in Schottky contact with the semiconductor layer in an opening of the insulation layer and has a field plate overlying the insulation layer in a region around the opening.

### CITATION LIST

### Patent Literature

Patent Literature 1: JP 2017/45969A

### SUMMARY OF INVENTION

An insulating film provided on a semiconductor layer, such as the insulation layer in the Schottky barrier diode described in Patent Literature 1, also acts as a passivation film that suppresses surface leakage current flowing along the upper surface of the semiconductor layer. However, as a result of intensive study, the inventors of the present invention have found that, particularly when the semiconductor layer is formed of a gallium oxide-based semiconductor and a SiO₂ film is used as the insulating film on the semiconductor layer, there may be a problem that increasing the density of the insulating film causes an increase in surface leakage due to damage to the semiconductor layer during film formation, while decreasing the density of the insulating film causes a decrease in dielectric withstand voltage due to poor film quality.

It is an object of the invention to provide a Schottky barrier diode which includes a semiconductor layer formed of a gallium oxide-based semiconductor and a passivation film formed of SiO₂ to significantly suppress the surface leakage and significantly enhance the dielectric withstand voltage.

An aspect of the invention provides a Schottky barrier diode defined below.

A Schottky barrier diode, comprising:

an n-type semiconductor layer comprising a gallium oxide-based semiconductor;

an insulating film comprising SiO₂ and covering a portion of an upper surface of the n-type semiconductor layer; and

an anode electrode which is connected to the upper surface of the n-type semiconductor layer to form a Schottky junction with the n-type semiconductor layer and at least a portion of an edge of which is located on the insulating film,

wherein the insulating film further comprises a first layer in contact with the n-type semiconductor layer and a second layer on the first layer,

wherein a refractive index of the first layer is lower than a refractive index of the second layer, and

wherein the n-type semiconductor layer further comprises a guard ring surrounding a junction with the anode electrode.

### Advantageous Effects of Invention

According to an aspect of the invention, it is possible to provide a Schottky barrier diode which includes a semiconductor layer formed of a gallium oxide-based semiconductor and a passivation film formed of SiO₂ to significantly suppress the surface leakage and significantly enhance the dielectric withstand voltage.

### BRIEF DESCRIPTION OF DRAWINGS

FIGS. 1A and 1B are vertical cross-sectional views showing Schottky barrier diodes in an embodiment of the present invention.

FIG. 2 is a vertical cross-sectional view showing a Schottky barrier diode in the embodiment of the invention.

FIGS. 3A, 3B and 3C are vertical cross-sectional views showing Schottky barrier diodes used to examine electrical resistance of a guard ring.

FIG. 4 is a graph showing a box profile of an N-implanted region included in the Schottky barrier diode.

FIGS. 5A, 5B and 5C are graphs showing changes in current density when forward voltage is applied to the Schottky barrier diodes.

FIGS. 6A, 6B and 6C are graphs showing changes in current when forward voltage is applied to the Schottky barrier diodes.

FIGS. 7A, 7B and 7C are vertical cross-sectional views showing Schottky barrier diodes used to examine effects of an insulating film and the guard ring.

FIGS. 8A, 8B and 8C are graphs showing changes in current density when reverse voltage is applied to the Schottky barrier diodes.

FIG. 9 is a graph showing changes in current when reverse voltage is applied to the Schottky barrier diodes.

### DESCRIPTION OF EMBODIMENTS

(Configuration of a Schottky Barrier diode)

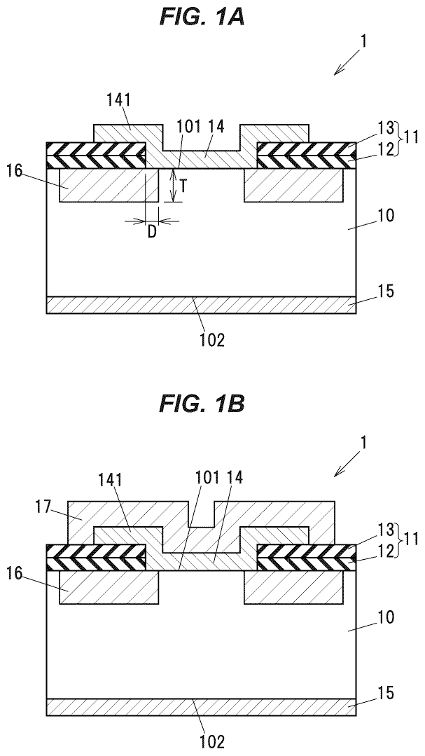

FIG. 1A is a vertical cross-sectional view showing a Schottky barrier diode 1 in an embodiment. The Schottky barrier diode 1 is a vertical Schottky barrier diode that includes a semiconductor layer formed of a gallium oxide-based semiconductor.

The Schottky barrier diode 1 includes an n-type semiconductor layer 10 formed of a gallium oxide-based semiconductor, an insulating film 11 formed of SiO₂ and covering a portion of an upper surface 101 of the n-type semiconductor layer 10, and an anode electrode 14 that is connected to the upper surface 101 of the n-type semiconductor layer 10, forms a Schottky junction with the n-type semiconductor layer 10 and is provided so that at least a portion of an edge is located on the insulating film 11. The insulating film 11 includes a first layer 12 in contact with the n-type semiconductor layer 10 and a second layer 13 on the first layer 12, a refractive index of the first layer 12 is lower than a refractive index of the second layer 13, and the n-type semiconductor layer 10 includes a guard ring 16 surrounding a junction with the anode electrode 14. In addition, a cathode electrode 15 is connected to a lower surface 102 of the n-type semiconductor layer 10 which is a surface on the opposite side to the upper surface 101.

In the Schottky barrier diode 1, an energy barrier at an interface between the anode electrode 14 and the n-type semiconductor layer 10 as viewed from the n-type semiconductor layer 10 is lowered by applying forward voltage between the anode electrode 14 and the cathode electrode 15, allowing a current to flow from the anode electrode 14 to the cathode electrode 15. On the other hand, when reverse voltage is applied between the anode electrode 14 and the cathode electrode 15, the current does not flow due to the Schottky barrier.

The n-type semiconductor layer 10 is formed of a single crystal of a gallium oxide-based semiconductor having a β-crystal structure. The gallium oxide-based semiconductor here means Ga₂O₃ or means Ga₂O₃ doped with an element such as Al or In. The gallium oxide-based semiconductor has a composition represented by, e.g., (GaₓAl_{y}In_{(1-x-y)})₂O₃ (0≤x≤1, 0≤y≤1, Ga₂O₃ has a wider band gap when doped with Al and a narrower band gap when doped with In.

The n-type semiconductor layer 10 contains a donor impurity such as Si or Sn. A donor concentration in the n-type semiconductor layer 10 is, e.g., not less than 1×10¹⁵ cm⁻³ and not more than 1×10¹⁷ cm⁻³. A thickness of the n-type semiconductor layer 10 is, e.g., not less than 2 μm and not more than 100 μm. The n-type semiconductor layer 10 is formed of, e.g., a substrate cut out of a single crystal grown by a liquid phase growth method.

The n-type semiconductor layer 10 may be a stacked body composed of plural semiconductor layers, and may be, e.g., composed of a substrate and an epitaxial layer epitaxially grown thereon.

In the Schottky barrier diode 1, at least a portion of the edge of the anode electrode 14 is placed on the insulating film 11 as described above. A portion 141 of the edge of the anode electrode 14, which is placed on the insulating film 11, is called a field plate, and a structure including the field plate is called a field-plate structure. By providing such a field-plate structure, it is possible to relax electric field concentration in the vicinity of the end portion of the anode electrode 14 and improve dielectric withstand voltage of the Schottky barrier diode 1.

To significantly improve the dielectric withstand voltage by the field-plate structure, it is preferable that the edge of the anode electrode 14 be placed on the insulating film 11 all around the perimeter. When, e.g., the planar shape of the insulating film 11 is an annular shape surrounding a junction between the n-type semiconductor layer 10 and the anode electrode 14, the planar shape of the portion 141 placed on the insulating film 11 is also an annular shape. The insulating film 11 is formed using plasma CVD capable of relatively good film formation at low temperature. The first layer 12 and the second layer 13, which constitute the insulating film 11 and have different refractive indices, can be formed differently from each other by controlling plasma power. The insulating film 11 is formed on the entire upper surface 101 of the n-type semiconductor layer 10, and is then patterned to expose a region of the upper surface 101 to which the anode electrode 14 is connected.

In general, the higher the density of the insulating film on which the field plate is placed, the greater the improvement in dielectric withstand voltage of the Schottky barrier diode. Increasing the plasma power of the plasma CVD can increase the density of the insulating film but also causes more damage to the upper surface of the semiconductor layer during film formation. As the damage increases, the interface state density on the upper surface of the semiconductor layer increases, hence, a leakage current flowing at the interface between the semiconductor layer and the insulating film (hereinafter, referred to as interface leakage current) increases. On the other hand, decreasing the plasma power of the plasma CVD can suppress damage to the upper surface of the semiconductor layer and thereby suppress an increase in the interface leakage current but causes a decrease in the density of the insulating film, hence, the dielectric withstand voltage of the Schottky barrier diode cannot be significantly improved.

In the Schottky barrier diode 1 of the embodiment of the invention, the insulating film 11 includes the first layer 12 in contact with the n-type semiconductor layer 10 and the second layer 13 on the first layer 12, and the refractive index of the first layer 12 is lower than the refractive index of the second layer 13, as described above. Here, there is a correlation between the density and the refractive index for the insulating film 11, where the higher the density, the higher the refractive index.

Thus, the first layer 12 is formed under conditions that plasma power is lower than that for the second layer 13. By forming the first layer 12 in contact with the n-type semiconductor layer 10 under the conditions of low plasma power, it is possible to suppress the damage to the n-type semiconductor layer 10 and suppress the interface leakage current.

Meanwhile, the second layer 13 having a higher refractive index than the first layer 12 has a higher density than the first layer 12. By including the second layer 13 having a high density in the insulating film 11, it is possible to increase the dielectric withstand voltage of the Schottky barrier diode 1. The second layer 13 having a high density is formed under conditions that plasma power of the plasma CVD is high, but damage to the n-type semiconductor layer 10 during film formation of the second layer 13 can be suppressed since the first layer 12 is present under the second layer 13.

That is, by using the insulating film 11 including the first layer 12 and the second layer 13, it is possible to achieve both improvement in the dielectric withstand voltage of the Schottky barrier diode 1 and suppression of the interface leak current.

To significantly suppress damage to the n-type semiconductor layer 10 during film formation of the first layer 12, the refractive index of the first layer 12 is preferably not more than 1.44. To significantly suppress damage to the n-type semiconductor layer 10 during film formation of the second layer 13, a thickness of the first layer 12 is preferably not less than 450 nm.

To significantly improve the dielectric withstand voltage of the Schottky barrier diode 1, the refractive index of the second layer 13 is preferably not less than 1.46 and a thickness of the second layer 13 is preferably not less than 20 nm. Meanwhile, to suppress stress generation, the thickness of the second layer 13 is preferably not more than 2000 nm. Furthermore, it has been observed that the interface leakage current tends to increase when the thickness of the second layer 13 is more than 100 nm, even though the cause has not been identified. Thus, it is particularly preferable that the thickness of the second layer 13 be not more than 100 nm.

The guard ring 16 is a region that contains an acceptor impurity and surrounds a junction between the anode electrode 14 and the n-type semiconductor layer 10. By using the guard ring 16, it is possible to relax electric field concentration at the end portion of the anode electrode 14 and improve the dielectric withstand voltage of the Schottky barrier diode 1.

The guard ring 16 is formed by, e.g., implanting ions of an acceptor impurity such as N (nitrogen) into the upper surface 101 of the n-type semiconductor layer 10 and subsequently performing annealing for damage recovery at about 900° C. in a nitrogen atmosphere.

When the guard ring 16 is defined as a region where the acceptor impurity concentration is 1×10¹⁷ atoms/cm³, a lateral distance D of a portion of the guard ring 16 in contact with the anode electrode 14 is preferably not less than 10 μm and a thickness T of the guard ring 16 is preferably not less than 10 nm, to significantly relax the electric field concentration by the guard ring 16.

FIG. 1B is a vertical cross-sectional view showing the Schottky barrier diode 1 when the anode electrode 14 is covered with a cover 17. The cover 17 covers the anode electrode 14 and is in contact with the upper surface of the insulating film 11 around the anode electrode 14. The cover 17 is electrically conductive and has, e.g., a Ti/Al stacked structure in which an Al film is stacked on a Ti film.

The anode electrode 14, when formed of Ni or Pt, has low adhesion with the insulating film 11 formed of SiO₂, hence, the field plate portion 141 of the anode electrode 14 may come off from the insulating film 11. In such a case, coming off of the portion 141 of the anode electrode 14 from the insulating film 11 can be suppressed by using the cover 17.

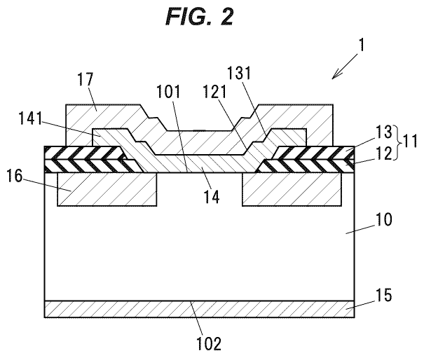

FIG. 2 is a vertical cross-sectional view showing the Schottky barrier diode 1 when the inner side surface of the insulating film 11 is inclined. In the Schottky barrier diode 1 shown in FIG. 2, the inner sides of the first layer 12 and the second layer 13 of the insulating film 11, i.e., a side surface 121 and a side surface 131 on the anode electrode 14 side, are inclined so as to face obliquely upward.

When the side surface 121 and the side surface 131 face obliquely upward, the electric field concentration can be relaxed more effectively than when the side surface 121 and the side surface 131 are vertical or face obliquely downward.

By controlling an etching rate of wet etching at the time of patterning the first layer 12 and the second layer 13, the side surface 121 and the side surface 131 can be inclined so as to face obliquely upward. Here, if the first layer 12 and the second layer 13 having different densities are etched under the same conditions, it is difficult to incline both the side surface 121 and the side surface 131 so as to face obliquely upward since the etching rates are different. Therefore, it is required to separately perform the etching of the first layer 12 and the etching of the second layer 13 under different conditions.

After etching the second layer 13, the first layer 12 is etched using a mask larger than the second layer 13. This causes the position of the side surface 121 to be shifted inward relative to the position of the side surface 131, allowing a step to be provided as shown in FIG. 2. It is thereby possible to relax the electric field concentration further effectively.

It is also possible to control the inclination angles of the side surface 121 and the side surface 131 by controlling the etching rate, etc., of wet etching at the time of patterning the first layer 12 and the second layer 13. To enhance the effect of relaxing electric field concentration, the inclination angles of the side surface 121 and the side surface 131 are preferably not less than from a direction perpendicular to the upper surface 101 of the n-type semiconductor layer

The Schottky barrier diode 1 is preferably configured such that the inner side surface of the insulating film 11 is inclined, the n-type semiconductor layer 10 includes the guard ring 16, and the anode electrode 14 is covered with the cover 17, as shown in FIG. 2.

(Evaluation of the Schottky barrier diode)

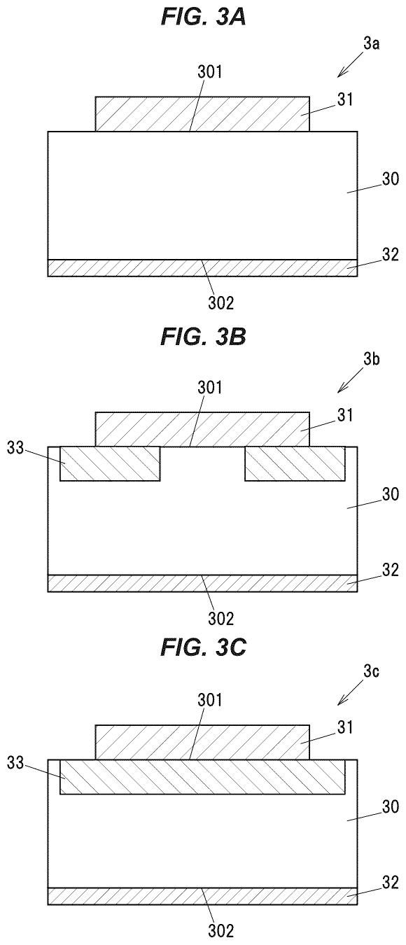

FIGS. 3A, 3B and 3C are vertical cross-sectional views showing Schottky barrier diodes 3a, 3b, 3c used to examine electrical resistance of the guard ring 16 of the Schottky barrier diode 1.

The Schottky barrier diode 3a shown in FIG. 3A includes an n-type semiconductor layer formed of β-Ga₂O₃, an anode electrode 31 formed on an upper surface 301 of the n-type semiconductor layer 30, and a cathode electrode 32 formed on a lower surface 302 of the n-type semiconductor layer 30. The Schottky barrier diode 3b shown in FIG. 3B differs from the Schottky barrier diode 3a in that an annular N-implanted region 33 into which N is ion-implanted is provided in the n-type semiconductor layer 30. The Schottky barrier diode 3c shown in FIG. 3C differs from the Schottky barrier diode 3b in that the N-implanted region 33 is provided to cover the entire area below the anode electrode 31.

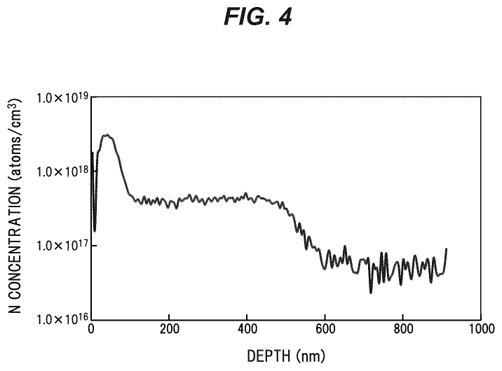

FIG. 4 is a graph showing a box profile of the N-implanted region 33 included in the Schottky barrier diodes 3b, 3c. The N-implanted region 33 was formed by multiple implantations of N ions under the conditions shown in Table 1 below.

TABLE 1

| | Energy | Implantation amount |
|---|---|---|
| Ion species | (keV) | (atoms/cm²) |
| N | 350 | 2.50 × 10¹³ |
| | 230 | 1.20 × 10¹³ |
| | 150 | 1.00 × 10¹³ |
| | 90 | 7.00 × 10¹² |
| | 50 | 4.50 × 10¹² |
| | 25 | 5.00 × 10¹³ |
| | 10 | 1.20 × 10¹³ |

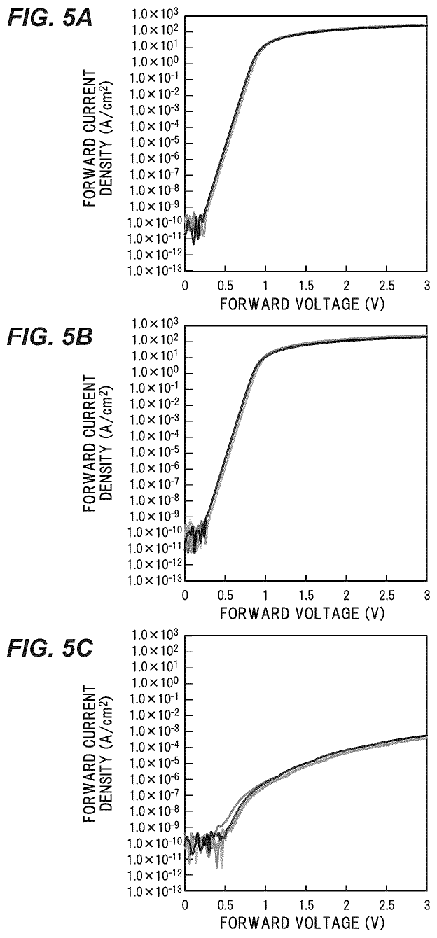

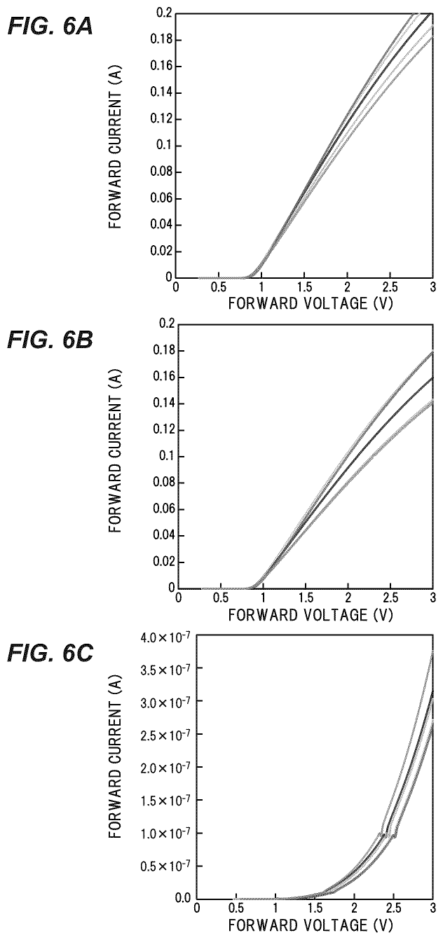

FIGS. 5A, 5B and 5C are graphs respectively showing changes in current density when forward voltage is applied to the Schottky barrier diodes 3a, 3b, 3c. FIGS. 6A, 6B and 6C are graphs respectively showing changes in current when forward voltage is applied to the Schottky barrier diodes 3a, 3b, 3c. The results of plural measurements conducted each under the same conditions are shown in FIGS. 5A, 5B, 5C, 6A, 6B and 6C.

From these measurement results, on-resistances of the Schottky barrier diodes 3a, 3b and 3c are respectively 8.15 mΩcm², 7.77 mΩcm² and 2.56 MΩcm². Meanwhile, volume resistivities of the Schottky barrier diodes 3a, 3b and 3c are respectively converted to 135 Ωcm, 130 Ωcm and 42.7 Ωcm. Based on these results, electric resistance of the Schottky barrier diode 3c is not less than 100 million times that of the Schottky barrier diodes 3a and 3b. Thus, the N-implanted region 33 and the guard ring 16 of the Schottky barrier diode 1 corresponding to the N-implanted region 33 can be defined as a region with an electrical resistance which is not less than 100 million times that of the surrounding region into which no acceptor impurity is implanted.

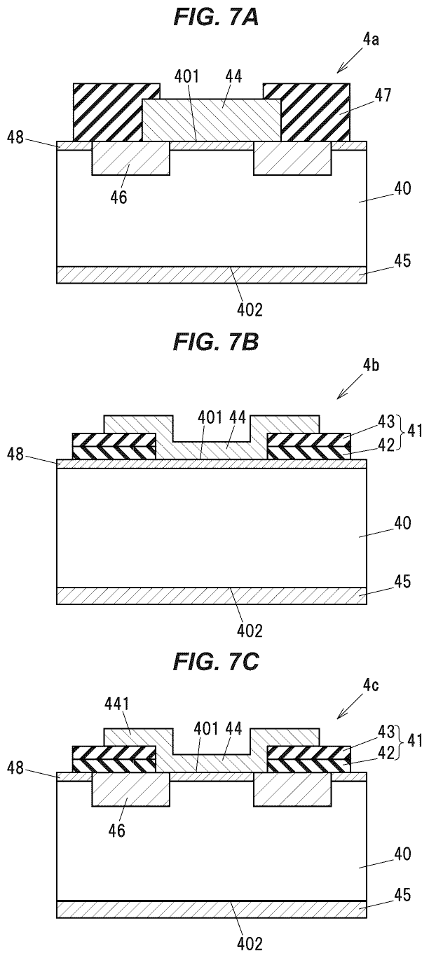

FIGS. 7A, 7B and 7C are vertical cross-sectional views showing Schottky barrier diodes 4a, 4b, 4c used to examine effects of the insulating film 11 and the guard ring 16 of the Schottky barrier diode 1.

The Schottky barrier diode 4a shown in FIG. 7A includes an n-type semiconductor layer formed of β-Ga₂O₃, an anode electrode 44 formed on an upper surface 401 of the n-type semiconductor layer 40, a cathode electrode 45 formed on a lower surface 402 of the n-type semiconductor layer 40, a guard ring 46 as a region in the n-type semiconductor layer 40 into which N is ion-implanted, and an annealing altered layer 48. The Schottky barrier diode 4a also includes a polyimide protective material to protect the area around the anode electrode 44.

The Schottky barrier diode 4b shown in FIG. 7B includes the n-type semiconductor layer formed of β-Ga₂O₃, an insulating film 41 formed of SiO₂ and covering a portion of the upper surface 401 of the n-type semiconductor layer 40, the anode electrode 44 that is connected to the upper surface 401 of the n-type semiconductor layer 40, forms a Schottky junction with the n-type semiconductor layer 40 and is provided so that an edge thereof is located on the insulating film 41, the cathode electrode 45 formed on the lower surface 402 of the n-type semiconductor layer 40, and the annealing altered layer 48. The insulating film 41 includes a first layer 42 in contact with the n-type semiconductor layer 40 and a second layer 43 on the first layer 42, and a refractive index of the first layer 42 is lower than a refractive index of the second layer 43. The planar shape of the insulating film 41 is an annular shape surrounding a junction between the n-type semiconductor layer 40 and the anode electrode 44.

The Schottky barrier diode 4c shown in FIG. 7C corresponds to the Schottky barrier diode 1 including the insulating film 11 and the guard ring 16 shown in FIG. 1A and differs from the Schottky barrier diodes 4a and 4b in that it includes both the insulating film 41 and the guard ring 46. The annealing altered layer 48 included in the Schottky barrier diodes 4a-4c is an altered layer that is unintentionally formed on the surface of the n-type semiconductor layer 40 during annealing. This annealing altered layer 48 can be removed by dry etching or wet etching, etc.

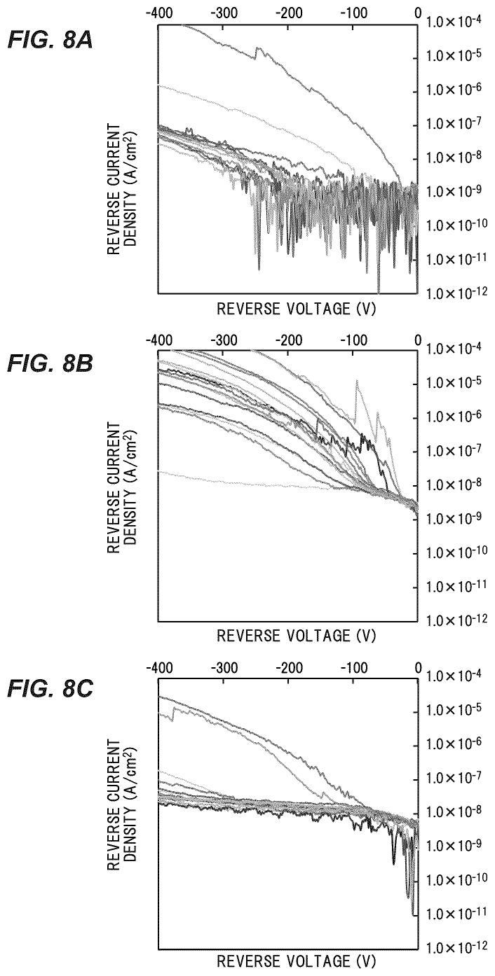

FIGS. 8A, 8B and 8C are graphs respectively showing changes in current density when reverse voltage is applied to the Schottky barrier diodes 4a, 4b and 4c. The results of plural measurements conducted under the same conditions are shown in each of FIGS. 8A, 8B and 8C.

FIGS. 8A, 8B and 8C show that when both the guard ring 46 and the insulating film 41 are used, the current which flows when reverse voltage is applied is smaller than when using only one of the guard ring 46 and the insulating film 41.

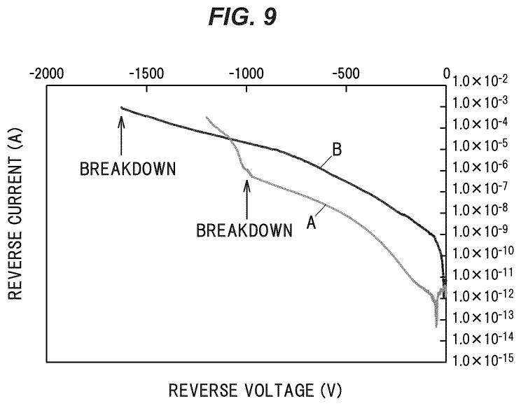

FIG. 9 is a graph showing changes in current when reverse voltage is applied to the Schottky barrier diode 4a having the guard ring 46 and the Schottky barrier diode 4c having both the guard ring 46 and the insulating film 41. In FIG. 9, A indicates the characteristics of the Schottky barrier diode 4a and B indicates the characteristics of the Schottky barrier diode 4c.

FIG. 9 shows that when both the guard ring 46 and the insulating film 41 are used, the breakdown voltage is higher than when using only the guard ring 46.

Based on the measurement results in FIGS. 8A, 8B, 8C and 9, the breakdown voltage is improved particularly effectively by using the insulating film 11 and the guard ring 16 together in the Schottky barrier diode 1 in the embodiment of the invention.

(Method for manufacturing the Schottky barrier diode) An example of a manufacturing method when the Schottky barrier diode 1 has the configuration shown in FIG. 2 will be described below.

Firstly, a gallium oxide-based semiconductor substrate is prepared as the n-type semiconductor layer 10, and ultrasonic cleaning with an organic solvent, hydrofluoric acid cleaning and SPM cleaning, etc., are performed as pre-process cleaning.

Next, the upper surface 101 of the n-type semiconductor layer 10 is covered with a photoresist, and an alignment pattern is formed by dry etching. Then, N ion implantation is performed from above the patterned photoresist under the conditions shown in the above Table 1, etc. After that, heat treatment is performed in an N₂ atmosphere in a lamp furnace at 900° C. for 30 minutes, thereby forming the guard ring 16 in the vicinity of the surface of the n-type semiconductor layer 10.

Next, SiO₂ films to be the first layer 12 and the second layer 13 of the insulating film 11 are formed on the upper surface 101 by the CVD method. Then, after patterning a resist by photolithography on the upper SiO₂ film to be the second layer 13, wet etching using BHF as an etchant is performed using this resist as a mask, thereby forming the second layer 13 with the inclined side surface 131. Then, after patterning a resist by photolithography on the lower SiO₂ film to be the first layer 12, wet etching using BHF as an etchant is performed using this resist as a mask, thereby forming the first layer 12 with the inclined side surface 121.

Next, SPM cleaning and ultrapure water cleaning are performed as pretreatment, and then, a metal film, which is formed of Ni or Pt and is to be the anode electrode 14, is vapor-deposited on the upper surface 101 of the n-type semiconductor layer 10. The metal film is then patterned, thereby forming the anode electrode 14.

Next, a metal film having a Ti/Al stacked structure, etc., which is to be the cover 17, is deposited on the anode electrode 14. The metal film is then patterned in a larger pattern than the anode electrode 14, thereby forming the cover 17. After that, the lower surface 102 of the n-type semiconductor layer 10 is covered with a metal film having a Ti/Ni/Au stacked structure, etc., thereby forming the cathode electrode 15.

(Effects of the embodiment) According to the embodiment, it is possible to provide a Schottky barrier diode which includes a semiconductor layer formed of a gallium oxide-based semiconductor and a passivation film formed of SiO₂ to the significantly suppress the surface leakage and significantly enhance the dielectric withstand voltage.

Although the embodiment of the invention has been described, the invention is not intended to be limited to the embodiment, and the various kinds of modifications can be implemented without departing from the gist of the invention. In addition, the constituent elements in the embodiment can be arbitrarily combined without departing from the gist of the invention. In addition, the invention according to claims is not to be limited to the embodiment described above. Further, it should be noted that not all combinations of the features described in the embodiment are necessary to solve the problem of the invention.

### REFERENCE SIGNS LIST

1 SCHOTTKY DIODE
N-TYPE SEMICONDUCTOR LAYER
101 UPPER SURFACE
11 INSULATING FILM
12 FIRST LAYER
121 SIDE SURFACE
13 SECOND LAYER
131 SIDE SURFACE
14 ANODE ELECTRODE
141 PORTION
15 CATHODE ELECTRODE
16 GUARD RING

1. A Schottky barrier diode, comprising:
an n-type semiconductor layer comprising a gallium oxide-based semiconductor;
an insulating film comprising SiO₂ and covering a portion of an upper surface of the n-type semiconductor layer; and
an anode electrode which is connected to the upper surface of the n-type semiconductor layer to form a Schottky junction with the n-type semiconductor layer and at least a portion of an edge of which is located on the insulating film,
wherein the insulating film further comprises a first layer in contact with the n-type semiconductor layer and a second layer on the first layer,
wherein a refractive index of the first layer is lower than a refractive index of the second layer, and
wherein the n-type semiconductor layer further comprises a guard ring surrounding a junction with the anode electrode.
